(19) United States
(12) Patent Application Publication
(10) Pub. No.: US 2023/0104021 A1
(43) Pub. Date: Apr. 6, 2023

(54) SUPPORT STRUCTURE FOR FLEXIBLE PANEL, AND FLEXIBLE DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zhiliang JIANG, Beijing (CN); Pan ZHAO, Beijing (CN)

(21) Appl. No.: 17/909,099

(22) PCT Filed: Jul. 6, 2021
(86) PCT No.: PCT/CN2021/104718

§ 371 Date: Sep. 2, 2022

(30) Foreign Application Priority Data
Aug. 7, 2020 (CN) 202010791036.1

(51) Int. Cl. H05K 5/02

(52) U.S. Cl. CPC H05K 5/02

(57) ABSTRACT

The present disclosure provides a support structure for a flexible panel, and a flexible display device. The support structure includes a flat portion and at least one curved portion surrounding the flat portion, a boundary is formed between the curved portion and the flat portion, and the curved portion is bent with the boundary as a bending axis.

### CROSS-REFERENCE TO RELATED APPLICATION

This application claims a priority of the Chinese patent application No.202010791036.1 filed on Aug. 7, 2020, which is incorporated herein by reference in its entirety.

### TECHNICAL FIELD

The present disclosure relates to the field of display technology, in particular to a support structure for a flexible panel, and a flexible display device.

### BACKGROUND

When a foldable flexible panel is applied, the flexible panel is attached to a rigid support structure, so that the flexible panel is provided with a form matching the support structure. As shown in FIG. 1, usually the flexible panel is attached to a flat support structure 10 in the related art. Although the flexible panel is provided with a flat form through the attachment, it is impossible for a resultant product to achieve a three-dimensional (3D) effect.

### SUMMARY

An object of the present disclosure is to provide a support structure for a flexible panel, and a flexible display device, so as to solve the above-mentioned problem.

In order to achieve the above-mentioned purpose, the present disclosure provides the following technical solutions.

In one aspect, the present disclosure provides in some embodiments a support structure for a flexible panel, including a flat portion and at least one curved portion surrounding the flat portion, a boundary is formed between the curved portion and the flat portion, and the curved portion is bent with the boundary as a bending axis.

In a possible embodiment of the present disclosure, a curvature radius of the curved portion is greater than or equal to 9 mm.

In a possible embodiment of the present disclosure, the curved portion has a first length along an extension direction of the boundary, and a first width along a direction perpendicular to the boundary on a plane where the flat portion is located, and a ratio of the first length to the first width is greater than or equal to 29.

In a possible embodiment of the present disclosure, the first width is greater than or equal to 5.34 mm.

In a possible embodiment of the present disclosure, the curved portion has a height smaller than or equal to 0.75 mm in a normal direction of the flat portion.

In a possible embodiment of the present disclosure, the support structure includes two curved portions, a first curved portion of the two curved portions is arranged at a first side of the flat portion, and a second curved portion of the two curved portions is arranged at a second side of the flat portion opposite to the first side. A first boundary is formed between the first curved portion and the flat portion, and the first curved portion is bent with the first boundary as a bending axis. A second boundary is provided with the second curved portion and the flat portion, and the second curved portion is bent with the second boundary as a bending axis.

In a possible embodiment of the present disclosure, the support structure includes a steel sheet.

In another aspect, the present disclosure provides in some embodiments a flexible display device including the above-mentioned support structure.

In a possible embodiment of the present disclosure, the flexible display device further includes a flexible panel attached to the support structure.

In a possible embodiment of the present disclosure, an orthogonal projection of the flexible panel on the support structure coincides with the support structure.

In a possible embodiment of the present disclosure, an orthogonal projection of the flexible panel on the support structure is surrounded by the support structure.

In a possible embodiment of the present disclosure, the flexible panel includes an Organic Light-Emitting Diode (OLED) display panel.

In yet another aspect, the present disclosure provides in some embodiments a method for manufacturing the above-mentioned support structure, including forming the flat portion of the support structure and at least one curved portion surrounding the flat portion. A boundary is formed between the curved portion and the flat portion, and the curved portion is bent with the boundary as a bending axis.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing a conventional flat support structure;

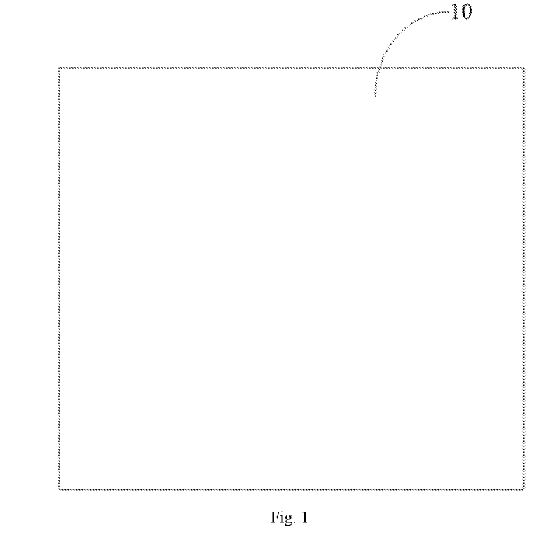

FIG. 2 is a schematic view showing a support structure according to one embodiment of the present disclosure; and

FIG. 3 is a sectional view of the support structure along line A1A2 in FIG. 2.

### DETAILED DESCRIPTION

The present disclosure will be described hereinafter in conjunction with the drawings and embodiments.

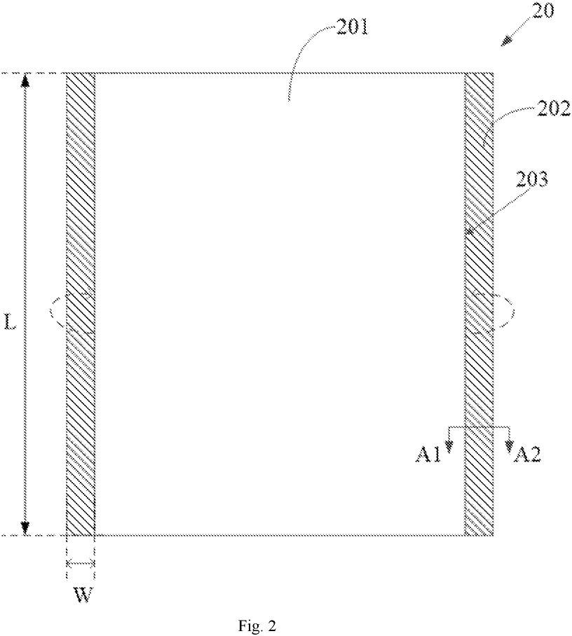

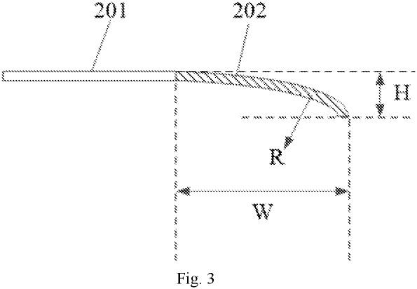

As shown in FIGS. 2 and 3, the present disclosure provides in some embodiments a support structure 20 for a flexible panel, which includes a flat portion 201 and at least one curved portion 202 surrounding the flat portion 201, a boundary 203 is formed between the curved portion 202 and the flat portion 201, and the curved portion 202 is bent with the boundary 203 as a bending axis.

To be specific, the support structure includes the flat portion 201 and the at least one curved portion 202 surrounding the flat portion 201. For example, the flat portion 201 is formed integrally with the at least one curved portion 202.

For example, the flat portion 201 is of a quadrilateral structure, e.g., a rectangular structure.

For example, the curved portion 202 is arranged at a first side of the flat portion 201, the boundary 203 is formed between the curved portion 202 and the flat portion 201, and the curved portion 202 is bendable with the boundary 203 as the bending axis. It should be appreciated that, the boundary 203 is a boundary of the flat portion 201 at the first side, i.e., a boundary between the first side of the flat portion 201 and the curved portion 202.

The support structure 20 includes the flat portion 201 and the curved portion 202, so after the foldable flexible panel is attached to the support structure 20, the flexible panel includes a flat region attached to the flat portion 201 and a curved region attached to the curved portion 202. After the flexible panel is attached to the support structure 20, it is able for a resultant product to achieve a 3D effect, thereby to improve competitiveness of the product.

Usually, a cover plate of the flexible panel is made of polyimide. When the flexible panel is attached to the support structure 20, the cover plate easily bounces, and the flexible panel is separated from the support structure 20, thereby the performance of the product may be deteriorated.

As shown in FIGS. 2 and 3, based on the above, in some embodiments of the present disclosure, a curvature radius R of the curved portion 202 is greater than or equal to 9 mm.

For example, the curvature radius of the curved portion 202 is greater than or equal to 9.88 mm.

More detailedly, the curved portion 202 is a continuous curved in a cross section of the support structure along line A1A2, and when the curve is divided into a plurality of segments at a certain length, each segment has a corresponding curvature radius. For example, the curvature radius of the curved portion 202 is a minimum curvature radius in the curvature radii of the segments.

When the curvature radius of the curved portion 202 is greater than or equal to 9 mm, the curved portion 202 is provided with a relatively large curvature radius. The larger the curvature radius of the curved portion 202, the smaller the bending level of the curved portion 202. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

As shown in FIGS. 2 and 3, in some embodiments of the present disclosure, the curved portion 202 has a first length L along an extension direction of the boundary 203, and a first width W along a direction perpendicular to the boundary 203 on a plane where the flat portion 201 is located, and a ratio of the first length L to the first width W is greater than or equal to 29.

For example, a length of the flat portion 201 is equal to the first length L in the extension direction of the boundary 203, and a width of the flat portion 201 is greater than the first width in the direction perpendicular to the boundary 203.

For example, the ratio of the first length L to the first width W is greater than or equal to 29.897.

In the above-mentioned support structure 20, when the ratio of the first length to the first width is greater than or equal to 29, the curved portion 202 is provided with a large length-to-width ration. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

As shown in FIGS. 2 and 3, in some embodiments of the present disclosure, the first width is greater than or equal to 5.34 mm.

In some embodiments of the present disclosure, a height H of the curved portion 202 is smaller than or equal to 0.75 mm in a normal direction of the flat portion 201.

For example, the height of the curved portion 202 is smaller than or equal to 0.747 mm in the normal direction of the flat portion 201.

In the above-mentioned support structure 20, when the first width is greater than or equal to 5.34 mm and the height of the curved portion 202 is smaller than or equal to 0.75 mm in the normal direction of the flat portion 201, the curved portion 202 is provided with an appropriate width and an appropriate height. In this way, when the flexible panel is attached to the support structure 20, it is able to improve a bending effect and a display effect of the flexible panel in a better manner.

As shown in FIGS. 2 and 3, in some embodiments of the present disclosure, the support structure 20 includes two curved portions 202, a first curved portion of the two curved portions 202 is arranged at a first side of the flat portion 201, and a second curved portion of the two curved portions 202 is arranged at a second side of the flat portion 201 opposite to the first side. A first boundary is formed between the first curved portion and the flat portion 201, and the first curved portion is bent with the first boundary as a bending axis. A second boundary is provided with the second curved portion and the flat portion201, and the second curved portion is bent with the second boundary as a bending axis.

To be specific, the first curved portion of the two curved portions 202 is arranged at the first side of the flat portion 201, the first boundary is formed between the first curved portion and the flat portion 201, and the first curved portion is bent with the first boundary as the bending axis. For example, a curvature radius of the first curved portion is greater than or equal to 9 mm, a ratio of a first length to a first width of the first curved portion is greater than or equal to 29, the first width is greater than or equal to 5.34 mm, and a height of the first curved portion is smaller than or equal to 0.75 mm in the normal direction of the flat portion 201.

The second curved portion of the two curved portions 202 is arranged at the second side of the flat portion 201, the second boundary is formed between the second curved portion and the flat portion 201, and the second curved portion is bent with the second boundary as the bending axis. For example, a curvature radius of the second curved portion is greater than or equal to 9 mm, a ratio of a first length to a first width of the second curved portion is greater than or equal to 29, the first width is greater than or equal to 5.34 mm, and a height of the second curved portion is smaller than or equal to 0.75 mm in the normal direction of the flat portion 201.

For example, as shown in FIG. 2, the first side is a right side, and the second side is a left side.

When the support structure 20 includes the first curved portion 202 and the second curved portion 202, it is able to bend the support structure 20 at two opposite sides, thereby to bend the flexible panel attached to the support structure 20 at two opposite sides.

In some embodiments of the present disclosure, the support structure includes a steel sheet.

For example, the support structure is a Steel Use Stainless (SUS) sheet.

The present disclosure further provides in some embodiments a flexible display device including the above-mentioned support structure 20.

After the above-mentioned support structure 20 is attached to a flexible panel, it is able for a resultant product to achieve a 3D effect. In addition, for the above-mentioned support structure 20, the curved portion is provided with a relatively large curvature radius, so that the curved portion 202 has a relatively small bending level. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

In addition, in the above-mentioned support structure 20, the curved portion 202 is provided with a relatively large length-to-width ration. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

Furthermore, in the above-mentioned support structure 20, the first width is greater than or equal to 5.34 mm and the height of the curved portion 202 is smaller than or equal to 0.75 mm in the normal direction of the flat portion 201, so that the curved portion 202 is provided with an appropriate width and an appropriate height. In this way, when the flexible panel is attached to the support structure 20, it is able to improve a bending effect and a display effect of the flexible panel in a better manner.

Hence, when the display device includes the above-mentioned support structure 20, it also has the above-mentioned beneficial effects, which will not be particularly defined herein.

It should be appreciated that, the flexible display device may be any product or member having a display function, e.g., television, display, digital photo frame, foldable mobile phone, or tablet computer.

In some embodiments of the present disclosure, the flexible display device further includes a flexible panel attached to the support structure 20.

The flexible panel includes a foldable flexible panel. For example, in actual use, the foldable flexible panel is capable of being folded in the middle of a display region.

When the flexible panel is fully attached to the support structure 20, it is able to achieve the above-mentioned beneficial effects, which will not be particularly defined herein.

In some embodiments of the present disclosure, an orthogonal projection of the flexible panel on the support structure 20 coincides with the support structure 20. In this case, the flexible panel has a same area as the support structure 20, and when they are attached to each other, a boundary of the flexible panel completely coincides with a boundary of the support structure 20.

In some embodiments of the present disclosure, an orthogonal projection of the flexible panel on the support structure 20 is surrounded by the support structure 20. In this case, a minimum distance between a boundary of the orthogonal projection of the flexible panel on the support structure 20 and a boundary of the support structure 20 is smaller than or equal to 0.5 mm.

In some embodiments of the present disclosure, the flexible panel includes an OLED display panel.

When the flexible panel includes the OLED display panel, the flexible display device has such advantages as high brightness, low power consumption, rapid response, high definition, excellent flexibility and high luminous efficiency.

The present disclosure further provides in some embodiments a method for manufacturing the above-mentioned support structure 20, which includes forming the flat portion 201 of the support structure 20 and at least one curved portion 202 surrounding the flat portion 201. A boundary is formed between the curved portion 202 and the flat portion 201, and the curved portion 202 is bent with the boundary as a bending axis.

After the support structure 20 manufactured by the above-mentioned method is attached to a flexible panel, it is able for a resultant product to achieve a 3D effect. In addition, for the above-mentioned support structure 20, the curved portion is provided with a relatively large curvature radius, so that the curved portion 202 has a relatively small bending level. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

In addition, in the support structure 20 manufactured through the above-mentioned method, the curved portion 202 is provided with a relatively large length-to-width ration. In this way, when the flexible panel is attached to the support structure 20, a relatively small bounce is applied to a portion of the flexible panel attached to the curved portion 202, so it is able to reduce a bouncing probability of the cover plate of the flexible panel, and prevent the flexible panel from being separated from the support structure 20 in a better manner, thereby to improve the performance of the product after the flexible panel is attached to the support structure 20.

Furthermore, in the support structure 20 manufactured through the above-mentioned method, the first width is greater than or equal to 5.34 mm and the height of the curved portion 202 is smaller than or equal to 0.75 mm in the normal direction of the flat portion 201, so that the curved portion 202 is provided with an appropriate width and an appropriate height. In this way, when the flexible panel is attached to the support structure 20, it is able to improve a bending effect and a display effect of the flexible panel in a better manner.

It should be appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A support structure for a flexible panel, comprising a flat portion and at least one curved portion surrounding the flat portion, wherein a boundary is formed between the curved portion and the flat portion, and the curved portion is bent with the boundary as a bending axis.

2. The support structure according to claim 1, wherein a curvature radius of the curved portion is greater than or equal to 9 mm.

3. The support structure according to claim 1, wherein the curved portion has a first length along an extension direction of the boundary, and a first width along a direction perpendicular to the boundary on a plane where the flat portion is located, and a ratio of the first length to the first width is greater than or equal to 29.

4. The support structure according to claim 3, wherein the first width is greater than or equal to 5.34 mm.

5. The support structure according to claim 1, wherein the curved portion has a height smaller than or equal to 0.75 mm in a normal direction of the flat portion.

6. The support structure according to claim 1, wherein the support structure comprises two curved portions, a first curved portion of the two curved portions is arranged at a first side of the flat portion, and a second curved portion of the two curved portions is arranged at a second side of the flat portion opposite to the first side, wherein a first boundary is formed between the first curved portion and the flat portion, and the first curved portion is bent with the first boundary as a bending axis, and wherein a second boundary is provided with the second curved portion and the flat portion, and the second curved portion is bent with the second boundary as a bending axis.

7. The support structure according to claim 1, wherein the support structure comprises a steel sheet.

8. A flexible display device, comprising a support structure for a flexible panel, wherein the support structure comprises a flat portion and at least one curved portion surrounding the flat portion, wherein a boundary is formed between the curved portion and the flat portion, and the curved portion is bent with the boundary as a bending axis.

9. The flexible display device according to claim 8, further comprising a flexible panel attached to the support structure.

10. The flexible display device according to claim 9, wherein an orthogonal projection of the flexible panel on the support structure coincides with the support structure.

11. The flexible display device according to claim 9, wherein an orthogonal projection of the flexible panel on the support structure is surrounded by the support structure.

12. The flexible display device according to claim 9, wherein the flexible panel comprises an Organic Light-Emitting Diode (OLED) display panel.
